(19) United States
(12) Patent Application Publication
(10) Pub. No.: US 2026/0122972 A1
(43) Pub. Date: Apr. 30, 2026

(54) THIN FILM TRANSISTOR AND MANUFACTURING METHOD THEREFOR, AND DISPLAY PANEL

(71) Applicant: Yungu (Gu’an) Technology Co., Ltd., Langfang (CN)

(72) Inventors: Fa-Hsyang CHEN, Langfang (CN); Guowen YAN, Langfang (CN); Lin XU, Langfang (CN); Dejian WANG, Langfang (CN); Lidong DING, Langfang (CN); Xiaoqi SUN, Langfang (CN)

(73) Assignee: Yungu (Gu’an) Technology Co., Ltd., Langfang (CN)

(21) Appl. No.: 19/430,323

(22) Filed: Dec. 23, 2025

Related U.S. Application Data
(63) Continuation of application No. PCT/CN2023/134330, filed on Nov. 27, 2023.

(30) Foreign Application Priority Data
Jun. 30, 2023 (CN) 202310798733.3

(51) Int. Cl. H10D 30/67; H10D 30/01

(52) U.S. Cl. CPC H10D 30/6755; H10D 30/0312; H10D 30/6733

(57) ABSTRACT

The present disclosure provides a thin film transistor and a manufacturing method therefor, an array substrate, and a display panel. The thin film transistor includes a substrate and an active layer and a first gate electrode both located on the substrate. The active layer includes a first film layer and a second film layer stacked on the substrate, the second film layer is located between the first film layer and the first gate electrode, the first film layer and the second film layer are semiconductor film layers, the second film layer has a lower mobility than the first film layer, and the second film layer has a larger density than the first film layer.

### CROSS-REFERENCE TO RELATED APPLICATIONS

The present application is a continuation application of International Application No. PCT/CN 2023/134330, filed on Nov. 27, 2023, which claims priority to Chinese Patent Application No. 202310798733.3 filed on Jun. 30, 2023, both of which are incorporated herein by reference in their entireties.

### FIELD

The present disclosure relates to the field of display, and in particular to a thin film transistor and a manufacturing method therefor, and a display panel.

### BACKGROUND

With the development of information technology, usage of electronic display products in daily life is increasing. Thin film transistors serve as major switching elements in drive circuits of electronic display products. However, active layers in the existing thin film transistors are limited to their structural design and forming process, making it difficult to ensure high mobility and high stability while maintaining the film-forming effect, thereby limiting the further improvement of efficiency of the thin film transistors.

### SUMMARY

A first aspect of the present disclosure provides a thin film transistor including a substrate and an active layer and a first gate electrode both located on the substrate. The active layer includes a first film layer and a second film layer stacked on the substrate, the second film layer is located between the first film layer and the first gate electrode, the first film layer and the second film layer are semiconductor film layers, the second film layer has a lower mobility than the first film layer, and the second film layer has a larger density than the first film layer.

In the above embodiments, the first film layer has a relatively high mobility, and during operation of the thin film transistor, carriers accumulate on a surface of the first film layer facing the first gate electrode, and the high-density second film layer can improve the surface to avoid surface defects, thereby improving the performance of the thin film transistor.

A second aspect of the present disclosure provides a display panel including a thin film transistor in the first aspect described above.

A third aspect of the present disclosure provides a manufacturing method for a thin film transistor. The manufacturing method includes: providing a substrate; depositing, onto the substrate, a first semiconductor material film layer with a first mobility at a first film-forming rate and a second semiconductor material film layer with a second mobility at a second film-forming rate, where the first mobility is larger than the second mobility, and the first film-forming rate is larger than the second film-forming rate and the second semiconductor material film layer has a larger density than the first semiconductor material film layer; patterning the first semiconductor material film layer and the second semiconductor material film layer to form a first film layer and a second film layer, respectively; and depositing a first conductive material thin film onto the substrate and patterning the first conductive material thin film to form a first gate electrode, where the second film layer is formed between the first film layer and the first gate electrode.

### BRIEF DESCRIPTION OF THE DRAWINGS

FIG. 1 is a sectional view of a thin film transistor according to an embodiment of the present disclosure;

FIG. 2 is a sectional view of another thin film transistor according to an embodiment of the present disclosure;

FIG. 3 is a sectional view of another thin film transistor according to an embodiment of the present disclosure;

FIG. 4 is a sectional view of another thin film transistor according to an embodiment of the present disclosure;

FIG. 5 is a sectional view of an array substrate according to an embodiment of the present disclosure;

FIG. 6 is a planar structural schematic diagram of a display panel according to an embodiment of the present disclosure;

FIG. 7 is a sectional view of the display panel shown in FIG. 6 along M-N;

FIG. 8 is a flowchart of a manufacturing method for a thin film transistor according to an embodiment of the present disclosure; and

FIGS. 9 to 13 are diagrams showing the process of a manufacturing method for a thin film transistor according to an embodiment of the present disclosure.

### DETAILED DESCRIPTION OF THE EMBODIMENTS

In a thin film transistor, the quality of a channel surface affects mobility. In response to defects on the channel surface, the electrical properties and reliability of channels will deteriorate. In addition, during the manufacturing of components such as a dielectric layer in the thin film transistor, when harmful ions intrude into the channels, the electrical properties and reliability of the channels will also deteriorate.

Embodiments of the present disclosure provide a thin film transistor and a manufacturing method therefor, and a display panel to solve at least the above problems. The thin film transistor includes a substrate and an active layer and a first gate electrode both located on the substrate. The active layer includes a first film layer and a second film layer stacked on the substrate, the second film layer is located between the first film layer and the first gate electrode, the first film layer and the second film layer are semiconductor film layers, the second film layer has a lower mobility than the first film layer, and the second film layer has a larger density than the first film layer. In this design, the first film layer has a relatively high mobility, and during operation of the thin film transistor, carriers accumulate on a surface of the first film layer facing the first gate electrode, and the high-density second film layer can improve the surface to avoid surface defects, thereby improving the performance of the thin film transistor. In addition, the high-density second film layer has a strong ion blocking effect, which can protect the first film layer.

Structures involved in the thin film transistor and the manufacturing method therefor, and the display panel according to at least one embodiment of the present disclosure are described below with reference to the drawings. In these embodiments, a spatial rectangular coordinate system is established on the basis of a plane where the substrate in the thin film transistor is located (e.g., a display surface of the display panel) to describe positions of respective structures in the thin film transistor, an array substrate and the display panel. In this spatial rectangular coordinate system, an X-axis and a Y-axis are parallel to the substrate, and a Z-axis is perpendicular to the substrate.

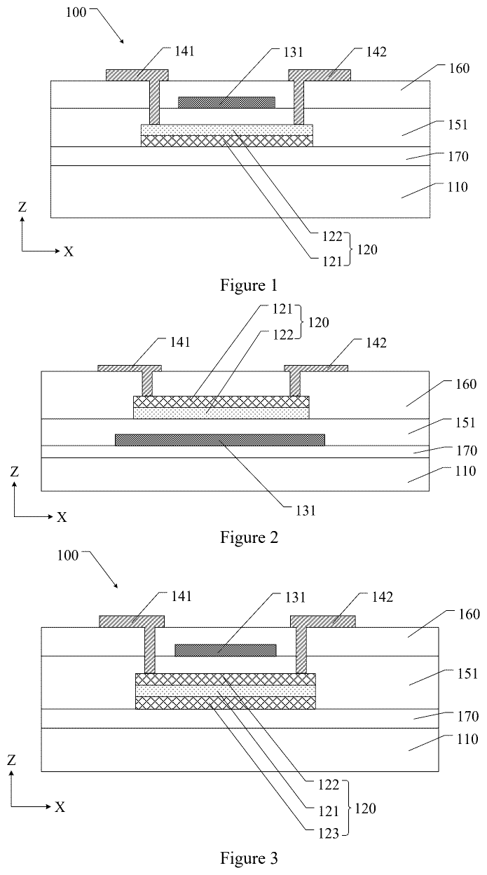

As shown in FIG. 1, a thin film transistor 100 includes an active layer 120 and a first gate electrode 131, the first gate electrode 131 being spaced apart from the active layer 120. The substrate 110 is configured to support the active layer 120 and the first gate electrode 131. By controlling a voltage applied to the first gate electrode 131, voltage fluctuations may be induced in the active layer 120 to generate carriers, thereby forming a current channel. In this way, the on-off of the thin film transistor 100 and the degree to which it is switched on can be controlled.

The active layer 120 includes a first film layer 121 and a second film layer 122 stacked together. The first film layer 121 is formed of a semiconductor material with a high mobility and the second film layer 122 is formed of a semiconductor material with a low mobility, and a surface of the first film layer 121 that is in contact with the second film layer 122 serves as a main channel for a two-dimensional electron gas (carriers). The second film layer 121 has a higher density than the first film layer 121, and the compactness of the second film layer 121 will be higher than the compactness of the first film layer 121. In a film-forming process, the high-compactness second film layer 122 has a high degree of surface planarization, which can improve surface defects of the first film layer 121 to ensure electrical properties and stability of the active layer. Furthermore, the high-compactness second film layer 122 provides a superior ion blocking effect, which can protect the first film layer 121.

It should be noted that, in the embodiments of the present disclosure, “density” refers to the mass density of a film layer, and the high density of the film layer indicates that atoms, molecules, or crystal lattice structures of the film layer are arranged densely, thereby providing superior barrier properties.

For example, as shown in FIG. 1, the thin film transistor 100 may further include a source electrode 141 and a drain electrode 142, and the source electrode 141 and the drain electrode 142 are connected to the active layer 120. The active layer 120 may be divided into a channel area, a source area, and a drain area. The channel area is located between the source area and the drain area, and the channel area corresponds to the first gate electrode 131. That is, an orthographic projection of the channel area onto the substrate is within an orthographic projection of the first gate electrode 131 onto the substrate, or the orthographic projection of the channel area onto the substrate overlaps with the orthographic projection of the first gate electrode 131 onto the substrate. The source area and the drain area may be located at two ends of the active layer 120 respectively, with the source area for connection to the source electrode 141 (electrical connection, e.g., ohmic contact), and the drain area for connection to the drain electrode 142 (electrical connection, e.g., ohmic contact). For example, after a voltage is applied to the first gate electrode 131, a channel opens (depending on materials of the active layer, the channel state may be reversed in this case, which may transition from open to closed), and a current (electrical signal) on the source electrode 141 is conducted to the drain electrode 142 through the active layer 120.

For example, in at least one embodiment of the present disclosure, as shown in FIG. 1, the thin film transistor 100 may further include a first gate insulation layer 151 and an interlayer dielectric layer 160 to define respective structures in the thin film transistor 100. For example, the first gate insulation layer 151 is located between the first gate electrode 131 and the active layer 120 to space the first gate electrode 131 from the active layer 120. The interlayer dielectric layer 160 is located between a source/drain electrode layer (including the source electrode 141 and the drain electrode 142) and the active layer 120 to space the source/drain electrode layer from the active layer 120.

For example, in at least one embodiment of the present disclosure, as shown in FIG. 1, the thin film transistor 100 may further include a buffer layer 170 between the substrate 110 and the active layer 120. The buffer layer 170 may block harmful ions intruding from the substrate 110 into the active layer 120.

It should be noted that, in the embodiments of the present disclosure, it is sufficient to ensure that the density of the second film layer is higher than the density of the first film layer and that the mobility of the second film layer is higher than the mobility of the first film layer. There are no limitations on the specific manufacturing process and specific materials of the first film layer and the second film layer. The manufacturing process and different selections of specific materials of the first film layer and the second film layer and the structure of the thin film transistor under the corresponding selection will be illustratively described below.

In some embodiments of the present disclosure, the first film layer and the second film layer each are formed by a semiconductor film layer through physical vapor deposition, and the power for physical vapor deposition corresponding to the semiconductor film layer that forms the first film layer is larger than the power for physical vapor deposition corresponding to the semiconductor film layer that forms the second film layer, and the density of the second film layer is larger than the density of the first film layer. Since the film-forming rate for the film layer formed by physical vapor deposition at low power is low, the film layer may have a high density. Therefore, by controlling the power for physical vapor deposition, the density difference between the first film layer and the second film layer can be controlled. For example, the power for physical vapor deposition that forms a first semiconductor material film layer may be 4 to 6 KW, and the power for physical vapor deposition that forms a second semiconductor material film layer may be 2 to 4 KW.

In some other embodiments of the present disclosure, the first film layer is formed by a semiconductor film layer through physical vapor deposition, and the second film layer is formed by a semiconductor film layer through atomic layer deposition, and the density of the second film layer is larger than the density of the first film layer. For example, the rate for forming the first film layer by physical vapor deposition ranges from 80 Å/s to 120 Å/s, and the rate for forming the second film layer by atomic layer deposition ranges from 20 Å/s to 60 Å/s.

Atomic layer deposition (ALD) is a surface deposition technique that enables the manufacturing of high-quality nanomaterials by depositing, layer by layer, a thin film of an atomic thickness on the surface of a material. The technical advantages of ALD include: high precision control is achieved; the thickness and properties of a thin film are controlled precisely by controlling the thickness and composition of each layer; a uniform thin film is formed on the structured surface and the quality and stability of the thin film are improved; and the operation is carried out at a low temperature, reducing the formation of impurities, thereby improving the purity of the thin film. Therefore, the film layer formed by ALD has good uniformity, and the film layer has a uniform surface, with a low risk of surface defects.

For example, the density of the first film layer is not greater than 5 g/cm³, and the density of the second film layer may be 5 to 7 g/cm³. It should be noted that, the actual densities of the first and second film layers may be designed according to specific process requirements and are not limited to the above numerical ranges.

For example, in the embodiments of the present disclosure, when the first film layer has a high mobility and a low density, the material of the first film layer is not limited, which can be determined based on actual process requirements. For example, the first film layer is made of a material including at least one of In, Ga, Zn or Sn. For example, in one embodiment, the material of the first film layer is one of IGZO, IGZTO, IZO, or IGO. For example, further, the mobility of the first film layer is not less than 20 cm²/Vs.

For example, in the embodiments of the present disclosure, when the second film layer has a low mobility and a high density, the material of the second film layer is not limited, which can be determined based on actual process requirements. For example, the second film layer is made of a material including at least one of In, Ga or Zn. For example, in one embodiment, the material of the second film layer is IGZO. For example, further, the mobility of the second film layer is not greater than 15 cm²/Vs.

For example, as shown in FIG. 1, the first film layer 121 and the second film layer 122 are in contact with each other, and the first film layer 121 and the second film layer 122 may be prepared in the same patterning process to simplify the manufacturing process flow of the active layer 120. In this case, patterns of the first film layer 121 and the second film layer 122 substantially overlap, i.e., an orthographic projection of the first film layer 121 onto the substrate 110 overlaps with an orthographic projection of the second film layer 122 onto the substrate 110.

It should be noted that, in the embodiments of the present disclosure, when the first film layer is a semiconductor layer and the thin film transistor includes only one gate electrode (the first gate electrode), the thin film transistor may be configured as a top-gate thin film transistor or as a bottom-gate thin film transistor, as detailed below.

For example, in some embodiments of the present disclosure, as shown in FIG. 1, when the first film layer 121 is a semiconductor layer, the first film layer 121 is located between the second film layer 122 and the substrate 110, that is, the thin film transistor 100 is a top-gate thin film transistor.

It should be noted that, both ends of the first film layer need to be doped (e.g., heavily doped) to become conductive, which is conducive to ensuring an electrical connection of the active layer to the source electrode and the drain electrode; and when the thin film transistor is a top-gate thin film transistor, the design thickness of the second film layer can be reduced to ensure that the configuration of the second film layer will not adversely affect the doping of the first film layer, for example, the second film layer has a smaller thickness than the first film layer.

For example, the thickness of the first film layer is 100 to 500 Å, such as 200 Å, 300 Å and 400 Å, and/or, the thickness of the second film layer is 10 to 100 Å, such as 20 Å, 40 Å, 60 Å and 80 Å.

For example, in some other embodiments of the present disclosure, as shown in FIG. 2, when the first film layer 121 is a semiconductor layer, the second film layer 122 is located between the first film layer 121 and the substrate 110, that is, the thin film transistor 100 is a bottom-gate thin film transistor.

For example, as shown in FIG. 2, when the thin film transistor 100 is a bottom-gate thin film transistor, an orthographic projection of the active layer 120 onto the substrate 110 is within an orthographic projection of the first gate electrode 131 onto the substrate 110. In this way, it is possible to avoid that the configuration of the first gate electrode 131 adversely affects the flatness of the active layer 120. In addition, the first gate electrode 131 may shield light transmitted from a side of the substrate 110 to reduce photogenerated carriers in the active layer 120. In addition, the first gate electrode 131 may shield harmful ions intruding from the substrate 110 into the active layer 120.

In at least one embodiment of the present disclosure, as shown in FIG. 3, the active layer 120 may further include a third film layer 123. The third film layer 123 is located on a side of the first film layer 121 away from the first gate electrode 131, and the third film layer 123 is made of a semiconductor material. The third film layer 123 has a lower mobility than the first film layer 121, and the third film layer 123 has a larger density than the first film layer 121. Thus, the third film layer 123 and the second film layer 122 can protect the first film layer 121 from both sides, preventing harmful ions in other dielectric layers (such as the gate insulation layer) from intruding into the first film layer 121.

It should be noted that the mobility of the third film layer is lower than the mobility of the first film layer, and therefore the first film layer is still used for forming channels.

In some embodiments of the present disclosure, the first film layer and the third film layer each are formed by a semiconductor film layer through physical vapor deposition, and the power for physical vapor deposition corresponding to the semiconductor film layer that forms the first film layer is larger than the power for physical vapor deposition corresponding to the semiconductor film layer that forms the third film layer, and the density of the third film layer is larger than the density of the first film layer. Since the film-forming rate for the film layer formed by physical vapor deposition at low power is low, the film layer may have a high density. Therefore, by controlling the power for physical vapor deposition, the density difference between the first film layer and the third film layer can be controlled.

In some other embodiments of the present disclosure, the first film layer is formed by a semiconductor film layer through physical vapor deposition, and the third film layer is formed by a semiconductor film layer through atomic layer deposition, and the density of the third film layer is larger than the density of the first film layer.

For example, the density of the third film layer may be 5 to 7 g/cm³.

For example, in the embodiments of the present disclosure, when the third film layer has a low mobility and a high density, the material of the third film layer is not limited, which can be determined based on actual process requirements. For example, the third film layer is made of a material including at least one of In, Ga or Zn. For example, in one embodiment, the material of the third film layer is IGZO. For example, further, the mobility of the third film layer is not greater than 15 cm²/Vs.

For example, in some embodiments of the present disclosure, as shown in FIG. 3, the third film layer 123 and the first film layer 121 may be prepared in the same patterning process to simplify the manufacturing process flow of the active layer 120. In this case, an orthographic projection of the third film layer 123 onto the substrate 110 overlaps with an orthographic projection of the first film layer 121 onto the substrate 110. For example, further, the orthographic projections of the first film layer 121, the second film layer 122 and the third film layer 123 onto the substrate 110 overlap, i.e., the first film layer 121, the second film layer 122 and the third film layer 123 are formed in the same patterning process. In this way, contamination (e.g., ion intrusion) to the first film layer 121 caused by contact with other materials (e.g., photoresist) can be avoided.

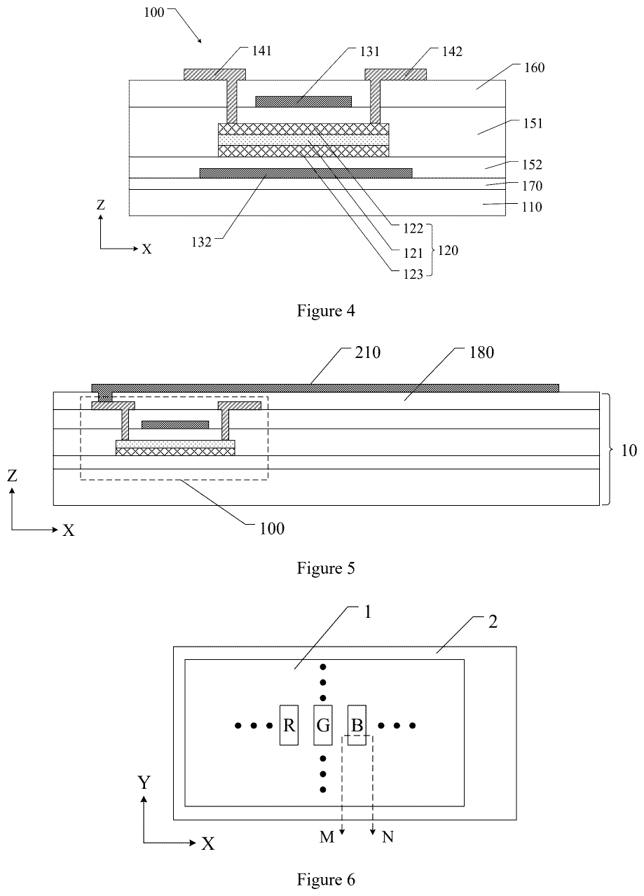

In at least one embodiment of the present disclosure, as shown in FIG. 4, the thin film transistor 100 may be designed as a dual-gate thin film transistor to increase the response speed of the thin film transistor. For example, the thin film transistor 100 may include a second gate electrode 132. The second gate electrode 132 is located on a side of the active layer 120 away from the first gate electrode 131.

It should be noted that, for the first gate electrode and the second gate electrode, the area of the one between the active layer and the substrate is larger than the area of the active layer to shield the active layer while ensuring the flatness of the active layer. By way of example, as shown in FIG. 4, the second gate electrode 132 is located between the active layer 120 and the substrate 110, and the orthographic projection of the active layer 120 onto the substrate 110 is within an orthographic projection of the second gate electrode 132 onto the substrate 110.

For example, as shown in FIG. 4, in response to being provided with the second gate electrode 132, the thin film transistor 100 may further include a second gate insulation layer 152 between the active layer 120 and the second gate electrode 132.

At least one embodiment of the present disclosure provides an array substrate, as shown in FIG. 5, which may include a drive circuit layer 10 including a plurality of pixel driving circuits. Each pixel driving circuit includes a plurality of thin film transistors 100, and at least one of the thin film transistors is the thin film transistor described in the above embodiments.

For example, each pixel driving circuit may include a plurality of thin film transistors (TFTs), capacitors, etc., which are, for example, formed in a variety of forms such as 2TIC (i.e., two thin film transistors (TFTs) and one capacitor (C)), 3T1C, or 7TIC. The pixel driving circuit is connected to a light-emitting device (see a light-emitting device 200 in the following embodiments) to control the on-ff state and the luminous brightness of the light-emitting device.

For example, in at least one embodiment of the present disclosure, as shown in FIG. 5, the array substrate may further include a planarization layer 180 and an anode 210 on the planarization layer 180. The planarization layer 180 is provided with vias, the pixel driving circuit is disposed corresponding to the anode 210, and a source or drain electrode of one thin film transistor in the pixel driving circuit is connected to the corresponding anode 210 through a corresponding one of the vias.

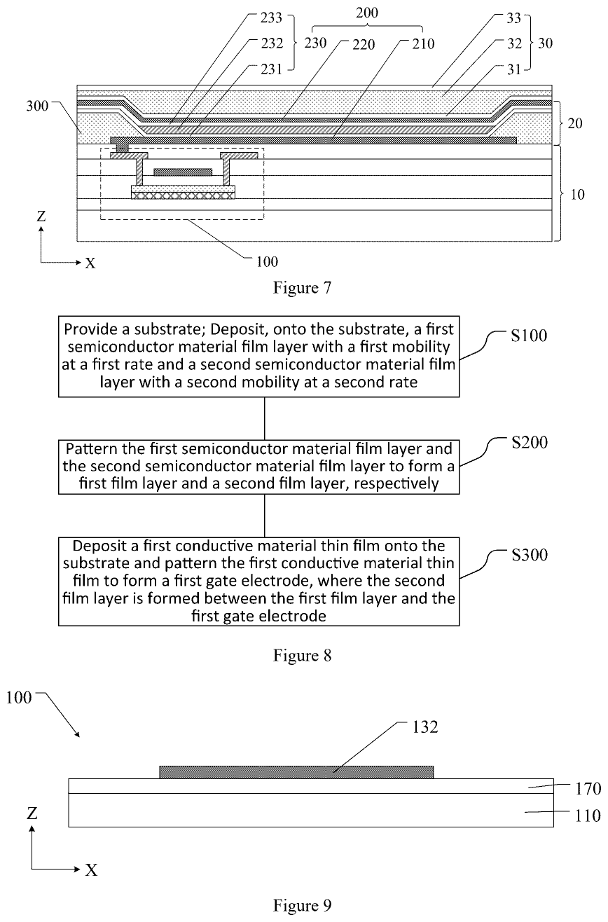

At least one embodiment of the present disclosure provides a display panel, and as shown in FIGS. 6 and 7, the display panel includes a display functional layer 20 and the array substrate 10 described in the above embodiments. The display panel may be divided into an active area 1 and a bezel area 2 on at least one side of the active area. A plurality of sub-pixels R, G, B are arranged in the active area 1. The display functional layer 20 is located on the array substrate 10 and includes a plurality of light-emitting devices 200. The light-emitting devices 200 are physical light-emitting structures of the sub-pixels R, G, B. For example, the light-emitting devices 200 in the sub-pixels R, G, B, respectively, are designed to emit red light (R), green light (G) and blue light (B). For example, the light-emitting devices 200 are connected to the pixel driving circuits in the array substrate 100.

Each of the light-emitting devices 200 may include an anode 210, a light-emitting functional layer 230 and a cathode 220 stacked sequentially on the array substrate. The light-emitting functional layer 230 may include a first communicating layer 231, a light-emitting layer 232, and a second communicating layer 233 stacked sequentially on the anode 210. For example, the first communicating layer 231 may include a hole injection layer and a hole transport layer, and may further include an electron blocking layer, etc. For example, the second communicating layer 233 may include an electron injection layer and an electron transport layer, and may further include a hole blocking layer, etc.

For example, as shown in FIG. 7, the display panel may further include a pixel defining layer 300. The pixel defining layer 300 includes a plurality of openings to define positions of the light-emitting devices. For example, a light-emitting layer of each light-emitting device 200 is within a corresponding one of the openings.

For example, as shown in FIG. 7, the display panel may further include an encapsulation layer 30 to cover the display functional layer 20 to protect the light-emitting devices 200. For example, the encapsulation layer 30 may include a first inorganic encapsulation layer 31, an organic encapsulation layer 32, and a second inorganic encapsulation layer 33 stacked sequentially on the display functional layer 20.

For example, in the embodiments of the present disclosure, the display panel may further include functional structures such as a touch-control functional layer, a polarizer, a lens layer, and a cover plate on a display side (e.g., on the encapsulation layer).

For example, in the embodiments of the present disclosure, the display panel may be any product or component having a display function, such as a television, a digital camera, a cell phone, a watch, a tablet computer, a laptop computer and a navigator.

At least one embodiment of the present disclosure provides a manufacturing method for a thin film transistor as described in the above embodiments. As shown in FIG. 8, the manufacturing method may include steps S100 to S300 as below.

S100: providing a substrate; and depositing, onto the substrate, a first semiconductor material film layer with a first mobility at a first film-forming rate and a second semiconductor material film layer with a second mobility at a second film-forming rate, where the first mobility is larger than the second mobility, and the first film-forming rate is larger than the second film-forming rate and the second semiconductor material film layer has a larger density than the first semiconductor material film layer.

S200: patterning the first semiconductor material film layer and the second semiconductor material film layer to form a first film layer and a second film layer, respectively.

S300: depositing a first conductive material thin film onto the substrate and patterning the first conductive material thin film to form a first gate electrode, where the second film layer is formed between the first film layer and the first gate electrode.

In the manufacturing method, the first film layer has a relatively high mobility, and during operation of the thin film transistor, carriers accumulate on a surface of the first film layer facing the first gate electrode, the high-density second film layer can improve the surface to avoid surface defects, thereby improving the performance of the thin film transistor.

For example, in some embodiments of the present disclosure, the step S100 may include: forming the first semiconductor material film layer and the second semiconductor material film layer by physical vapor deposition, respectively, where the power for physical vapor deposition that forms the first semiconductor material film layer is larger than the power for physical vapor deposition that forms the second semiconductor material film layer and the first film-forming rate is larger than the second film-forming rate and the density of the second film layer is larger than the density of the first film layer. In this design, for the specific materials of the first film layer and the second film layer, and their formation environments, reference may be made to the relevant description in the foregoing embodiments, which will not be repeated herein.

For example, in some other embodiments of the present disclosure, the step S100 may include: forming the first semiconductor material film layer by physical vapor deposition and forming the second semiconductor material film layer by atomic layer deposition and the first film-forming rate is larger than the second film-forming rate and the density of the second film layer is larger than the density of the first film layer. In this design, for the specific materials of the first film layer and the second film layer, and their formation environments, reference may be made to the relevant description in the foregoing embodiments, which will not be repeated herein.

For example, in at least one embodiment of the present disclosure, the manufacturing method may further include: depositing an insulation material between the first gate electrode and the active layer to form a first gate insulation layer, the first gate insulation layer spacing the first gate electrode from the active layer. For the positional relationship between the first gate insulation layer formed in this manner and the first gate electrode and the active layer, reference may be made to the relevant description in the foregoing embodiments, which will not be repeated herein.

For example, the manufacturing method further includes: depositing a conductive material film layer onto a side of the active layer away from the substrate, and performing a patterning process on the conductive material film layer to form a source electrode and a drain electrode, where the source electrode and the drain electrode are connected to two ends of the active layer, respectively. For the positional relationship between the source electrode and the drain electrode formed in this manner and the first gate electrode and the active layer, reference may be made to the relevant description in the foregoing embodiments, which will not be repeated herein.

For example, in at least one embodiment of the present disclosure, the manufacturing method may further include: depositing a third semiconductor material film layer with a third mobility at a third rate, where the first mobility is larger than the third mobility, and the first film-forming rate is larger than the third rate and the third semiconductor material film layer has a larger density than the first semiconductor material film layer; and patterning the third semiconductor material film layer to form a third film layer. In this design, for the specific material of the third film layer and its formation environment, reference may be made to the relevant description in the foregoing embodiments, which will not be repeated herein.

In the manufacturing method according to at least one embodiment of the present disclosure, the second mobility is equal to the third mobility. For example, the second film-forming rate is equal to the third rate and the density of the second film layer is equal to the density of the third film layer. The second film layer and the third film layer have the same mobility and density. For example, the second film layer and the third film layer may be made of the same material, to reduce manufacturing costs of the thin film transistor.

In at least one embodiment of the present disclosure, the manufacturing method may further include: after the first semiconductor material film layer, the second semiconductor material film layer and the third semiconductor material film layer are deposited, performing a patterning process on the first semiconductor material film layer, the second semiconductor material film layer and the third semiconductor material film layer simultaneously to form the first film layer, the second film layer and the third film layer, while enabling an orthographic projection of the first film layer onto the substrate, an orthographic projection of the second film layer onto the substrate and an orthographic projection of the third film layer onto the substrate to overlap. Thus, costs for the manufacturing process of the active layer can be saved. Furthermore, the second and third semiconductor material film layers can protect the first semiconductor material film layer, thereby reducing the risk of contamination to the active layer, especially the first film layer therein, during the manufacturing process.

In at least one embodiment of the present disclosure, the manufacturing method may further include: depositing a second conductive material thin film onto the substrate and patterning the second conductive material thin film to form a second gate electrode, where the second gate electrode is formed on a side of the active layer away from the first gate electrode. For the structure of the thin film transistor that is formed as a dual-gate thin film transistor, reference may be made to the relevant description in the foregoing embodiments, which will not be repeated herein. In addition, different methods may be selected for preparing the second gate electrode depending on whether the first gate electrode is above or below the active layer, as detailed below.

For example, in some embodiments of the present disclosure, in addition to the step of forming the first gate electrode on the side of the active layer away from the substrate, the manufacturing method further includes: before the active layer and the first gate electrode are formed, depositing a second conductive material thin film onto the substrate and patterning the second conductive material thin film to form a second gate electrode.

For example, in some other embodiments of the present disclosure, the manufacturing method may further include: before the active layer and the first gate electrode are formed and after the second gate electrode is formed, depositing an insulation material onto the substrate to form a second gate insulation layer to cover the second gate electrode.

In at least one embodiment of the present disclosure, the manufacturing method may further include: after the active layer and the first gate electrode are formed and before the second gate electrode is formed, depositing an insulation material onto the substrate to form a second gate insulation layer. For the positional relationship between the second gate insulation layer formed in this manner and other structures in the thin film transistor, reference may be made to the relevant description in the foregoing embodiments, which will not be repeated herein.

The following describes the process of the manufacturing method for a thin film transistor according to at least one embodiment of the present disclosure by taking the thin film transistor shown in FIG. 4 as an example. Specific reference is made to the process steps illustrated in FIGS. 9 to 13.

As shown in FIG. 9, a substrate 110 is provided and an insulation material film layer and a conductive material thin film (the second conductive material thin film described above) are sequentially deposited onto the substrate 110, the insulation material film layer forming a buffer layer 170, and the conductive material thin film is subjected to a patterning process to form a second gate electrode 132.

In the embodiments of the present disclosure, the patterning process may be a photolithographic patterning process, which, for example, may include: applying a photoresist on a structural layer to be patterned, exposing the photoresist using a mask, developing the exposed photoresist to obtain a photoresist pattern, etching (in some embodiment wet or dry etching) the structural layer using the photoresist pattern, and then, in one embodiment, removing the photoresist pattern. It should be noted that when the material of the structural layer includes the photoresist, the structural layer may be directly exposed by means of the mask to form the desired pattern.

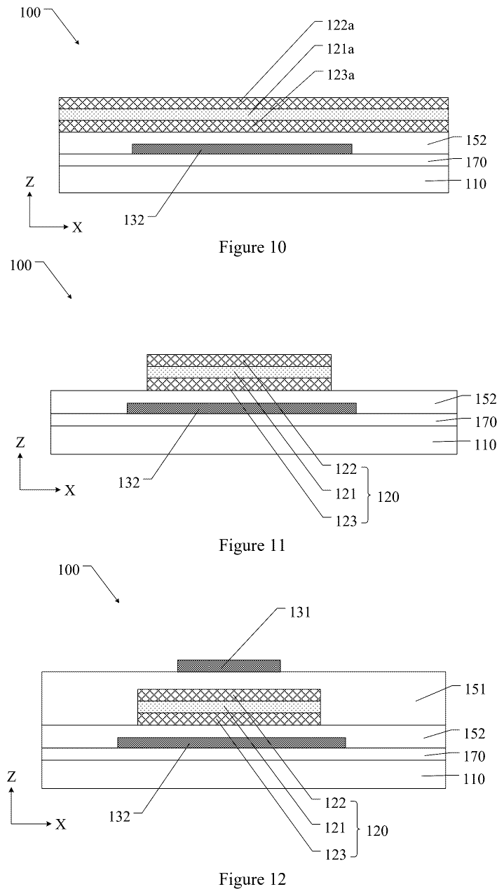

As shown in FIGS. 9 and 10, the insulation material film layer is deposited on the substrate 110 where the second gate electrode 132 is formed to form a second gate insulation layer 152; and then a third semiconductor material film layer 123a, a first semiconductor material film layer 121a, and a second semiconductor material film layer 122a are sequentially deposited onto the second gate insulation layer 152. The second semiconductor material film layer 122a and the third semiconductor material film layer 123a may be formed by atomic layer deposition, each of which may have a density of 5 to 7 g/cm³ and a thickness of 10 to 100 Å. The first semiconductor material film layer 121a may be formed by physical vapor deposition, which may have a density of not greater than 5 g/cm³, and a thickness of 100 to 500 Å.

As shown in FIGS. 10 and 11, the first semiconductor material film layer 121a, the second semiconductor material film layer 122a and the third semiconductor material film layer 123a are subjected to a patterning process to form a first film layer 121, a second film layer 122 and a third film layer 123, respectively, and the first film layer 121, the second film layer 122 and the third film layer 123 are stacked together to form an active layer 120.

For example, in the step shown in FIG. 11, two ends of the first film layer 121 (which are the source area and the drain area connected to the source electrode and the drain electrode, respectively) can be doped through the second film layer 122 and the two ends of the first film layer 121 are conductive.

It should be noted that, in some embodiments of the present disclosure, the active layer may be doped using the gate electrode as a mask after a gate electrode (e.g., the first gate electrode 131 shown in FIG. 12 below) is formed on the side of the active layer away from the substrate.

As shown in FIGS. 11 and 12, an insulation material is deposited onto the active layer 120 to form a first gate insulation layer 151; and a conductive material thin film (the first conductive material thin film described above) is then deposited onto the first gate insulation layer 151, and the conductive material thin film is subjected to a patterning process to form a first gate electrode 131.

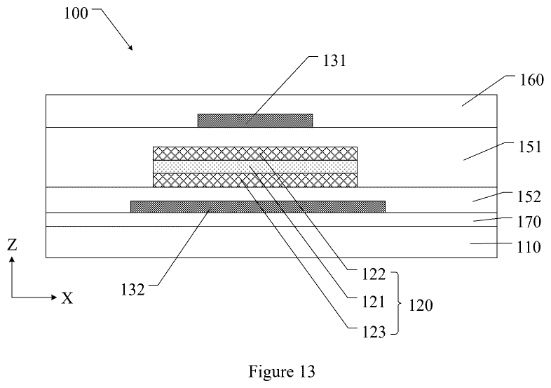

As shown in FIGS. 12 and 13, an insulation material film layer is deposited onto the substrate 110 where the first gate electrode 131 is formed to form an interlayer dielectric layer 160.

As shown in FIGS. 13 and 4, the interlayer dielectric layer 160 is subjected to a patterning process to form vias; and a conductive material thin film is deposited onto the interlayer dielectric layer 160, the conductive material thin film is subjected to a patterning process to form a source electrode 141 and a drain electrode 142, the source electrode 141 and the drain electrode 142 are connected to the active layer 120 through the vias in the interlayer dielectric layer 160.

What is claimed is:

1. A thin film transistor, comprising a substrate and an active layer and a first gate electrode both located on the substrate, wherein the active layer comprises a first film layer and a second film layer stacked on the substrate, and the second film layer is located between the first film layer and the first gate electrode; and
the first film layer and the second film layer are semiconductor film layers, the second film layer has a lower mobility than the first film layer, and the second film layer has a larger density than the first film layer.

2. The thin film transistor according to claim 1, wherein
the first film layer is made of a material comprising at least one of In, Ga, Zn or Sn; or
the second film layer is made of a material comprising at least one of In, Ga or Zn.

3. The thin film transistor according to claim 2, wherein
the material of the first film layer is one of IGZO, IGZTO, IZO or IGO, and the mobility of the first film layer is not less than 20 cm²/Vs; and
the material of the second film layer is IGZO, and the mobility of the second film layer is not greater than 15 cm²/Vs.

4. The thin film transistor according to claim 3, wherein the density of the first film layer is not greater than 5 g/cm³, and the density of the second film layer is 5 to 7 g/cm³.

5. The thin film transistor according to claim 4, wherein
an orthographic projection of the first film layer onto the substrate overlaps with an orthographic projection of the second film layer onto the substrate, and the first film layer is in direct contact with the second film layer.

6. The thin film transistor according to claim 5, wherein
the active layer is located between the first gate electrode and the substrate, and the second film layer has a smaller thickness than the first film layer; or
the first gate electrode is located between the active layer and the substrate, and an orthographic projection of the active layer onto the substrate is within an orthographic projection of the first gate electrode onto the substrate.

7. The thin film transistor according to claim 6, further comprising:
a first gate insulation layer between the first gate electrode and the active layer;
wherein the thin film transistor further comprises a source electrode and a drain electrode, the source electrode and the drain electrode being located on a side of the active layer away from the substrate, and two ends of the active layer being connected to the source electrode and the drain electrode, respectively.

8. The thin film transistor according to claim 7, wherein the active layer further comprises:
a third film layer located on a side of the first film layer away from the first gate electrode, the third film layer comprising a semiconductor material;
wherein the third film layer has a lower mobility than the first film layer, the third film layer has a larger density than the first film layer, and the first film layer is in direct contact with the third film layer.

9. The thin film transistor according to claim 8, wherein the third film layer is made of a material comprising at least one of In, Ga or Zn.

10. The thin film transistor according to claim 9, wherein the mobility of the third film layer is not greater than 15 cm²/Vs, and the density of the third film layer is 5 to 7 g/cm³.

11. The thin film transistor according to claim 10, wherein the orthographic projection of the first film layer onto the substrate overlaps with an orthographic projection of the third film layer onto the substrate.

12. The thin film transistor according to claim 1, further comprising a second gate electrode on a side of the active layer away from the first gate electrode.

13. A display panel, comprising a thin film transistor, wherein the thin film transistor comprising a substrate and an active layer and a first gate electrode both located on the substrate, wherein the active layer comprises a first film layer and a second film layer stacked on the substrate, and the second film layer is located between the first film layer and the first gate electrode; and the first film layer and the second film layer are semiconductor film layers, the second film layer has a lower mobility than the first film layer, and the second film layer has a larger density than the first film layer.

14. A manufacturing method for a thin film transistor, the manufacturing method comprising:
providing a substrate;
depositing, onto the substrate, a first semiconductor material film layer with a first mobility at a first film-forming rate and a second semiconductor material film layer with a second mobility at a second film-forming rate, wherein the first mobility is larger than the second mobility, and the first film-forming rate is larger than the second film-forming rate, wherein the second semiconductor material film layer has a larger density than the first semiconductor material film layer;
patterning the first semiconductor material film layer and the second semiconductor material film layer to form a first film layer and a second film layer, respectively; and
depositing a first conductive material thin film onto the substrate and patterning the first conductive material thin film to form a first gate electrode, wherein the second film layer is formed between the first film layer and the first gate electrode.

15. The manufacturing method according to claim 14, wherein depositing, onto the substrate, a first semiconductor material film layer with a first mobility at a first film-forming rate and a second semiconductor material film layer with a second mobility at a second film-forming rate comprises:
forming the first semiconductor material film layer and the second semiconductor material film layer by physical vapor deposition, respectively, wherein the power for physical vapor deposition that forms the first semiconductor material film layer is larger than the power for physical vapor deposition that forms the second semiconductor material film layer, wherein the first film-forming rate is larger than the second film-forming rate and the second film layer has a larger density than the first film layer.

16. The manufacturing method according to claim 15, wherein the power for physical vapor deposition that forms the first semiconductor material film layer is 4 to 6 KW, and the power for physical vapor deposition that forms the second semiconductor material film layer is 2 to 4 KW.

17. The manufacturing method according to claim 14, wherein the first semiconductor material film layer is formed by physical vapor deposition and the second semiconductor material film layer is formed by atomic layer deposition, wherein the first film-forming rate is larger than the second film-forming rate and the density of the second film layer is larger than the density of the first film layer.

18. The manufacturing method according to claim 17, wherein the first film-forming rate is 80 to 120 Å/s, and the second film-forming rate is 20 to 60 Å/s.

19. The manufacturing method according to claim 14, further comprising:
depositing a third semiconductor material film layer with a third mobility at a third rate, wherein the first mobility is larger than the third mobility, and the first film-forming rate is larger than the third rate, wherein the third semiconductor material film layer has a larger density than the first semiconductor material film layer; and
patterning the third semiconductor material film layer to form a third film layer;
wherein the second mobility is equal to the third mobility, and the second film-forming rate is equal to the third rate, wherein the density of the second film layer is equal to a density of the third film layer.

20. The manufacturing method according to claim 19, wherein the manufacturing method further comprises: after the first semiconductor material film layer, the second semiconductor material film layer and the third semiconductor material film layer are deposited, performing a patterning process on the first semiconductor material film layer, the second semiconductor material film layer and the third semiconductor material film layer simultaneously to form the first film layer, the second film layer and the third film layer, while enabling an orthographic projection of the first film layer onto the substrate, an orthographic projection of the second film layer onto the substrate and an orthographic projection of the third film layer onto the substrate to overlap.
